(19) United States
(12) Patent Application Publication
(10) Pub. No.: US 2016/0033658 A1
(43) Pub. Date: Feb. 4, 2016

(54) SEMICONDUCTOR RADIATION DETECTOR ARRAY

(71) Applicants: Hitachi High-Tech Science Corporation, Northridge, CA (US); Hitachi High-Technologies Science America, Inc, Northridge, CA (US)

(72) Inventors: Valeri Saveliev, Palmdale, CA (US); Shaul Barkan, Stevenson Ranch, CA (US); Gapasin Brilliante, Saugus, CA (US); Elena Damron, Palmdale, CA (US); Yen-Nai Wang, Los Angeles, CA (US)

(73) Assignees: HITACHI HIGH-TECHNOLOGIES SCIENCE AMERICA, INC, Northridge, CA (US); HITACHI HIGH-TECH SCIENCE CORPORATION, Northridge, CA (US)

(21) Appl. No.: 14/525,773

(22) Filed: Oct. 28, 2014

Related U.S. Application Data
(60) Provisional application No. 62/032,225, filed on Aug. 1, 2014.

(51) Int. Cl. G01T 1/24; H01L 31/115; H01L 31/028; H01L 25/04

(52) U.S. Cl. CPC G01T 1/243; H01L 25/042; H01L 31/115; H01L 31/028

(57) ABSTRACT

A radiation detector with improved performance includes a probe and a first detector element constructed from planar semiconductor material in the probe. The detector further includes a second detector element constructed from planar semiconductor material in the probe. The detector further includes a focal point located outside of the probe. The detector further includes a circuit in communication with the detector elements. The first and second detector elements face the focal point and have the same solid angle relative to the focal point. The detector elements generate signals in response to incident radiation. The circuit receives the signals generated by the detector elements.

### TECHNICAL FIELD

The apparatus described herein relates to radiation spectroscopy and imaging, and in particular, to detection of x-ray and light photons using semiconductor radiation detectors, and to methods for fabrication of such devices.

### BACKGROUND

Radiation or x-ray detectors can be constructed using silicon integrated circuit technology. The semiconductor radiation detector may also be referred to as a semiconductor detector, a radiation detector, or a detector. Radiation detectors are frequently used as a central component of spectrometers.

Semiconductor radiation detectors typically have an active volume, which is depleted of free charge carriers, and is used to absorb at least some of the radiation to generate charges. There has been a continuing effort in the development of semiconductor radiation detectors with better sensitivity, higher energy resolution, lower electronic noise and larger active area that can operate at or near room temperature. However, cooling the detector and input components of the amplification circuit generally reduces electronic noise and enhances spectroscopic performance of the system. In many applications, the detectors are also required to provide position or imaging information.

Some spectrometers have a long probe design for applications such as electron microscopy and many other x-ray fluorescence measurements. The detector needs to be placed in proximity to the samples being examined in order to assure a large solid angle of measurement. Very often, the access to the sample is limited, for example, by electron focusing lenses and/or other instruments and objects including the sample holder. For this reason, the front-end of these spectrometers is constructed as a long cylinder with a small diameter and the detector is placed at the front of the cylinder behind an entrance window.

Semiconductor radiation detectors have been fabricated through the construction of a planar device that can be fully depleted from a small electrode. U.S. Pat. No. 4,688,067 titled “Carrier Transport and Collection in Fully Depleted Semiconductors by a Combined Action of the Space Charge Field and the Field Due to Electrode Voltages” discloses a fully depletable semiconductor detector, which is often referred to as a drift detector. Similar structures are also disclosed in U.S. Pat. No. 4,837,607 titled “Large Area, Low Capacitance Semiconductor Arrangement” and U.S. Pat. No. 4,885,620 titled “Semiconductor Element.” An example of a drift detector is given in Large Area Silicon Drift Detectors for X-Rays-New Results, Jan S. Iwanczyk et al., IEEE Transactions on Nuclear Science, Vol. 46, No. 3, June 1999.

Semiconductor radiation detectors typically have an entrance window electrode to receive impinging radiation. In conventional semiconductor radiation detectors fabricated on n-type bulk material, the entrance window is typically uniformly doped with p+ impurities. The p+ impurity concentration at the entrance window is generally selected such that the depletion region comes close to the outer surface of the detector, but without actually touching the outer surface. Otherwise, large thermally-generated leakage currents may saturate the signal generated by detected radiation. Drift detectors, such as the one shown in FIGS. 2-4, usually use two superimposed electric fields.

For best detection results, it is also important to consider coupling between the detector and readout electronics. Semiconductor radiation detectors typically have a low capacitance structure. In order to improve electronic noise performance of the low capacitance detector structures, e.g., as disclosed in U.S. Pat. No. 4,688,067, the total input capacitance (including the detector, input transistor, and parasitic capacitance due to interconnections and support structures) should be kept very small. The traditional approach to minimizing the parasitic capacitance is based on the integration of the input transistor to the detector anode, as shown for example in U.S. Pat. No. 5,424,565 titled “Semiconductor Detector.”

Semiconductor radiation detectors also often include an outer guard structure at the perimeter of the detector. The outer guard structure can generally prevent premature breakdown, suppress surface leakage current and reduce electronic noise. Prior art detectors used biased or floating p+ rings as outer guard structures on n-type substrates.

Radiation detectors can be used in an array to increase the detection area and performance of the detector system. Since these detectors are fabricated using silicon wafers, they are generally arranged in a planar fashion relative to each other on a single wafer. However, this arrangement is not ideal because both the angle and solid angle of each detector will be different relative to the sample. Therefore, the optical coupling between the sample and the various detectors will be different and not ideal. This will degrade performance, particularly when the detectors are identical and the control software does not account for their angular and positional differences when taking measurements. There remains a need in the art for a radiation detector using an array of silicon wafer detectors with improved performance.

### BRIEF SUMMARY

A radiation detector with improved performance includes a probe and a first detector element constructed from planar semiconductor material in the probe. The detector further includes a second detector element constructed from planar semiconductor material in the probe. The detector further includes a focal point located outside of the probe. The detector further includes a circuit in communication with the detector elements. The first and second detector elements face the focal point and have the same solid angle relative to the focal point. The detector elements generate signals in response to incident radiation. The circuit receives the signals generated by the detector elements.

In some embodiments, the detector further includes a third detector element constructed from planar semiconductor material in the probe that faces the focal point and has the same solid angle relative to the focal point as the first and second detector elements. In some embodiments, the detector further includes a first axis intersecting a center of the first detector element and the focal point, a second axis intersecting a center of the second detector element and the focal point, and a third axis intersecting a center of the third detector element and the focal point—and the first, second, and third axes are located in one plane. In some embodiments, the detector further includes a housing, a proximal portion of the probe coupled to the housing, and a distal portion of the probe that contains the detector elements. In some embodiments, the detector further includes a probe axis that intersects the proximal portion and distal portion of the probe—the probe axis also intersects a center of the first detector element and the focal point. In some embodiments, the first and second detector elements abut one another. In some embodiments, the first and second detector elements are electrically connected to each other. In some embodiments, the detector further includes: a first axis intersecting a center of the first detector element and the focal point; a first major plane of the first detector element, the first axis being normal to the first major plane; a second axis intersecting a center of the second detector element and the focal point; and a second major plane of the second detector element, the second axis being normal to the second major plane. In some embodiments, the planar semiconductor material is a silicon wafer. In some embodiments, the probe has a concave tip. In some embodiments, the array is an x-ray detector.

A semiconductor radiation detector array with improved performance includes a first detector element constructed from planar semiconductor material. The array further includes a second detector element constructed from planar semiconductor material. The array further includes a focal point. The first and second detector elements facing the focal point and having the same solid angle relative to the focal point.

In some embodiments, the array further includes a third detector element constructed from planar semiconductor material that faces the focal point and has the same solid angle relative to the focal point as the first and second detector elements. In some embodiments, the array further includes a first axis intersecting a center of the first detector element and the focal point, a second axis intersecting a center of the second detector element and the focal point, and a third axis intersecting a center of the third detector element and the focal point—and the first, second, and third axes are located in one plane. In some embodiments, the first and second detector elements abut one another. In some embodiments, the first and second detector elements are electrically connected to each other. In some embodiments, the array further includes: a first axis intersecting a center of the first detector element and the focal point; a first major plane of the first detector element, the first axis being normal to the first major plane; a second axis intersecting a center of the second detector element and the focal point; and a second major plane of the second detector element, the second axis being normal to the second major plane. In some embodiments, the planar semiconductor material is a silicon wafer. In some embodiments, the array is an x-ray detector.

### BRIEF DESCRIPTION OF THE DRAWINGS

FIG. 1 is a perspective view of a long-probe radiation detector system that incorporates an array of radiation detectors according to the embodiments described herein.

FIG. 1A is a cross-sectional view showing internal components of a housing according to the embodiment shown in FIG. 1.

FIG. 2 is a cross-sectional schematic of a semiconductor radiation detector element according to the embodiment shown in FIG. 1.

FIG. 3 is a plan view schematic of a semiconductor radiation detector element shown in FIG. 2.

FIG. 4 is a plan view schematic of a prior art array of detector elements according to the embodiment shown in FIGS. 2 and 3 arranged in a planar fashion on a silicon wafer.

FIG. 5 is a diagram of the detector array according to the embodiment shown in FIG. 1.

FIG. 6A is an isometric view of the end of the probe according to the embodiment shown in FIG. 1 with bellows.

FIG. 6B is front planar view of the end of the probe shown in FIG. 6A.

### DETAILED DESCRIPTION

Described herein is a multi-element focal radiation detector constructed from a plurality of radiation detector elements. In several embodiments, the detector elements are constructed from a planar semiconductor material, such as a silicon wafer. The detector elements comprise an entrance window with a depletion region that is constructed from a semiconductor.

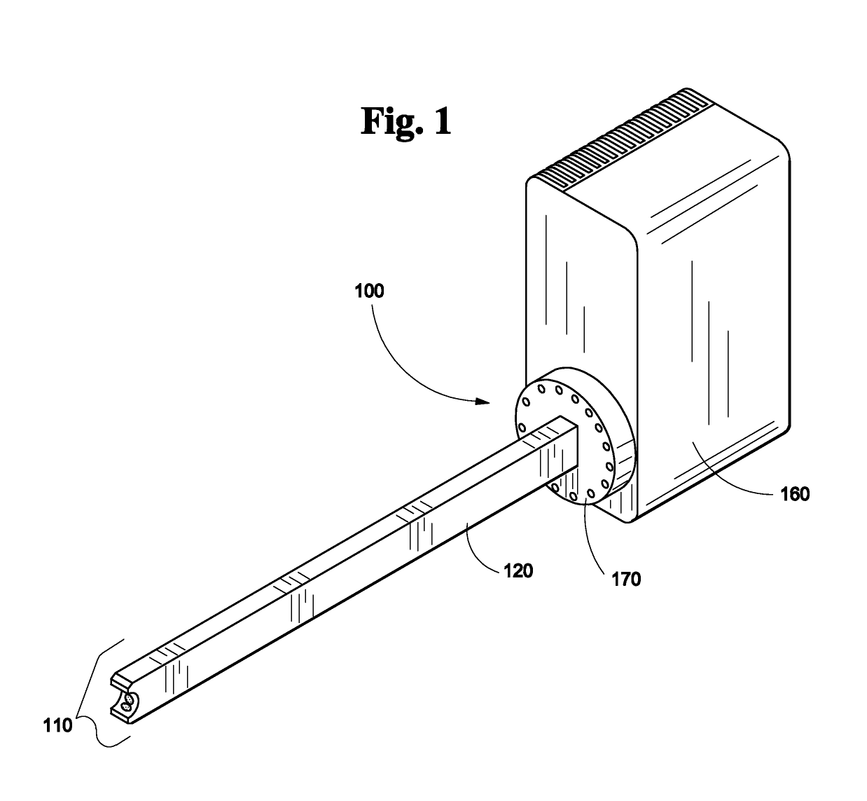

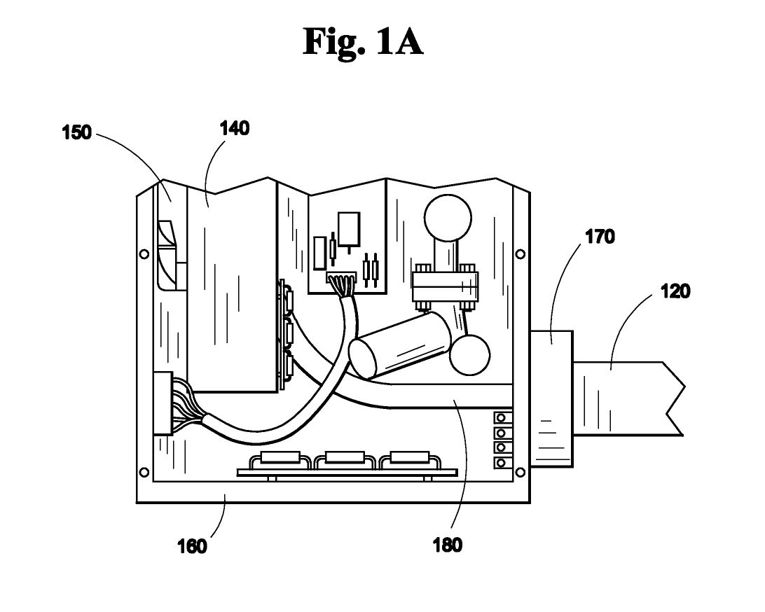

FIG. 1 is a perspective view of a long-probe radiation detector system 100 incorporating an array of radiation detectors according to the embodiments described herein. The array is located in the tip 110 of the shaft 120, which allows for easier access to a sample being scanned. The detector system 100 also includes an electronics housing 160 and a base plate 170 connecting the shaft 120 to the electronics housing 160. As can be seen in FIG. 1, the proximal portion of the shaft or probe 120 is coupled to the housing 160, while the distal portion contains the detector element array. The shaft 120 is elongated and has a major axis intersecting both the proximal and distal portions.

In certain embodiments, the radiation detection system 100 of the present invention includes a heat pipe based cooling. FIG. 1A is a cross-sectional view of the internal components of the housing 160. The housing 160 may contain a condenser, a heat sink 140, a fan 150, and a heat pipe 180 running from the heat sink 140 and into the shaft 120. A thermo electric cooler (not shown) may be coupled to the detector element array within the distal portion of the shaft 120. The heat pipe 180 has a first end (i.e., an evaporator end) thermally coupled to a hot side of the thermo electric cooler (single-stage or multi-stage) via an evaporator and a second end thermally coupled to the heat sink 140 via the condenser. This way, heat generated by the thermo electric cooler is transferred to the heat sink 140 through the heat pipe 180, which is dissipated to the surrounding environment via the fan 150.

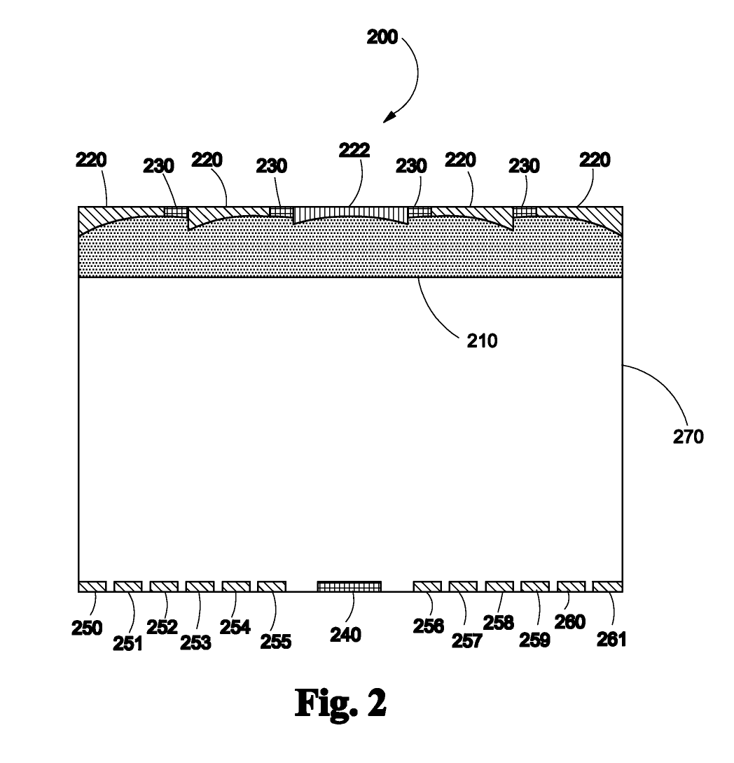

FIG. 2 is a cross-sectional schematic of a semiconductor radiation detector element 200 according to one embodiment. In this embodiment, detector element 200 includes a depleted p+ region 210 and a number of concentric undepleted p+ regions 220, 222. Detector element 200 further includes a series of concentric n+ regions 230.

In one embodiment, the doping concentrations in all p+ regions 220, 220 of the entrance electrode are substantially the same except for the doping concentration at the center p+ doped region 222. In this embodiment, the doping concentration at center p+ doped region 222 is greater than the product of the doping concentration of the bulk material and the wafer thickness, and the doping concentration at other p+ doped regions 220 is approximately 50% (3×1010 atoms/cm2) of the doping concentration at center p+ doped region 222, which is 6×1010 atoms/cm2.

Individually biasing entrance electrode segments typically provide distinct advantages. The bias voltage distribution at the entrance electrode segments may be adjusted in such a way as to minimize the transit time of the generated carriers. The individual biasing of the entrance electrode segments generally allows for more parallel and faster drift of the charge carriers over long distances, thus enabling the fabrication of devices with larger active areas and good timing characteristics.

Therefore, during operation of the semiconductor radiation detector in the embodiment illustrated in FIG. 2, p+ doped regions 220, 222 and n+ regions 230 that physically segment p+ doped regions 220, 222 are separately biased. For example, a biasing point is used to bias center p+ doped region 222, and separate biasing points are used for each concentric ring formed by the p+ regions 220 and n+ regions 230 surrounding it.

During operation, biasing voltages at the p+ doped regions 220, 222 range from −60 to −150 volts in some embodiments. In some embodiments, the biasing voltages at the n+ regions 230 are 10 to 20 Volts more positive than the biasing voltages at the neighboring p+ regions 220, 222. In some embodiments, p+ doped regions 220, 222 of detector element 200 may be variably doped. The p+ doped regions 220, 222 and/or n+ inserts 230 may be individually biased as the corresponding regions in semiconductor radiation detector element 200 of FIG. 2 in addition to being variably doped.

Detector element 200 also includes backside electrodes on the side of the bulk material, e.g., semiconductor wafer 270, opposite the side of the entrance electrode. The backside electrodes in this embodiment include an n+ anode 240 and multiple p+ cathodes 250-261. The multiple p+ cathodes 250-261 may also be referred to as rectifying electrodes or as electrodes that make up a rectifying electrode. In some embodiments, the n+ anode 240 has a circular or hexagonal shape. In other embodiments, n+ anode 240 may have other polygonal shapes, or a circular shape.

In this embodiment, the p+ cathodes 250-261 are fabricated as concentric rings, which may also be referred to as drift rings. In this embodiment, the p+ cathodes 255 and 256 are on the same ring and biased with substantially the same potential, the p+ cathodes 254 and 257 are on the same ring and biased with substantially the same potential, the p+ cathodes 253 and 258 are on the same ring and biased with substantially the same potential, and so on. In other embodiments, p+ cathodes 250-261 may have other polygonal shapes, such as hexagonal shape.

In this embodiment, the charges created by the detected radiation are collected by n+ anode 240 and provided to underlying readout electronics (not shown). In this embodiment, p+ cathodes 250-261 are biased at monotonically decreasing potentials (becoming more negative) in the radial direction away from the center as to produce a potential gradient from the front to the back of the detector element 200 so that the created charges are drifted toward n+ anode 240. For example, the potential at p+ cathodes 254 and 257 is more negative than the potential at p+ cathodes 255 and 256, the potential at p+ cathodes 253 and 258 is more negative than the potential at p+ cathodes 254 and 257, and so on.

In this embodiment, the n+ anode (detector anode) 240 has a voltage range from approximately 0 Volt (ground) to approximately −20 Volts with respect to ground. In some embodiments, the potential at p+ cathodes 255 and 256 is between approximately −10 Volts and approximately −40 Volts, and is typically (or approximately −20 Volts). When the detector area is approximately 0.5 cm2, the potential at the outer most p+ cathodes, which may be farther away from n+ anode 240 than the p+ cathodes 250 and 261, is between approximately −90 Volts and approximately −250 Volts (or approximately between −120 and −250 Volts).

Detector elements 200 having physical segmentation and biasing are particularly well suited for radiation detectors 100 with active area radius greater than a few mm (e.g., greater than 2-4 mm) although physical segmentation and biasing may also be applied to radiation detectors 100 having active areas smaller than a few mm.

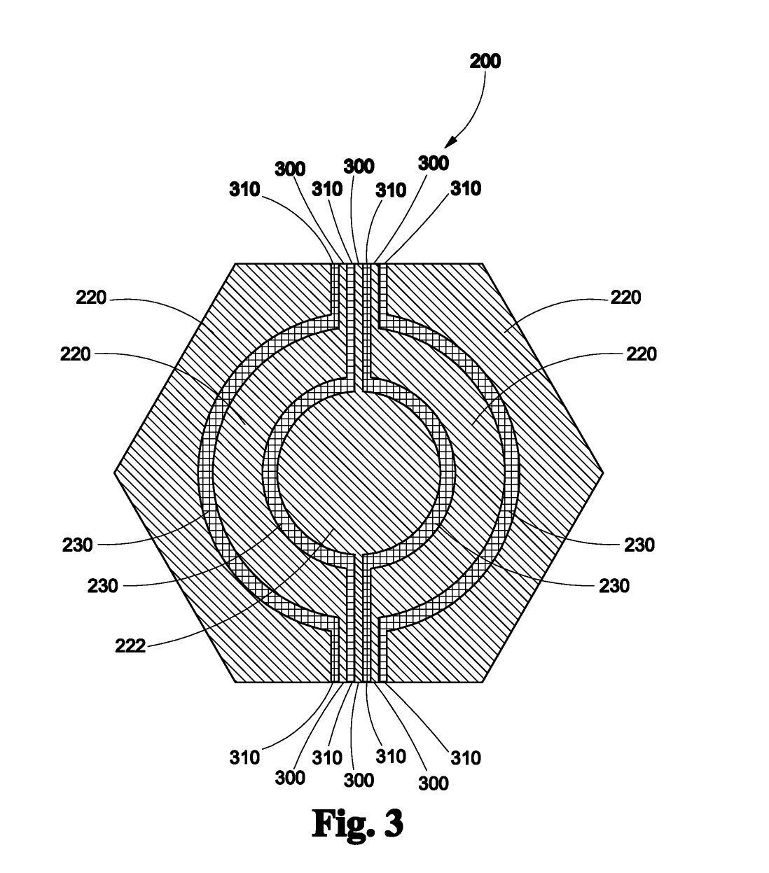

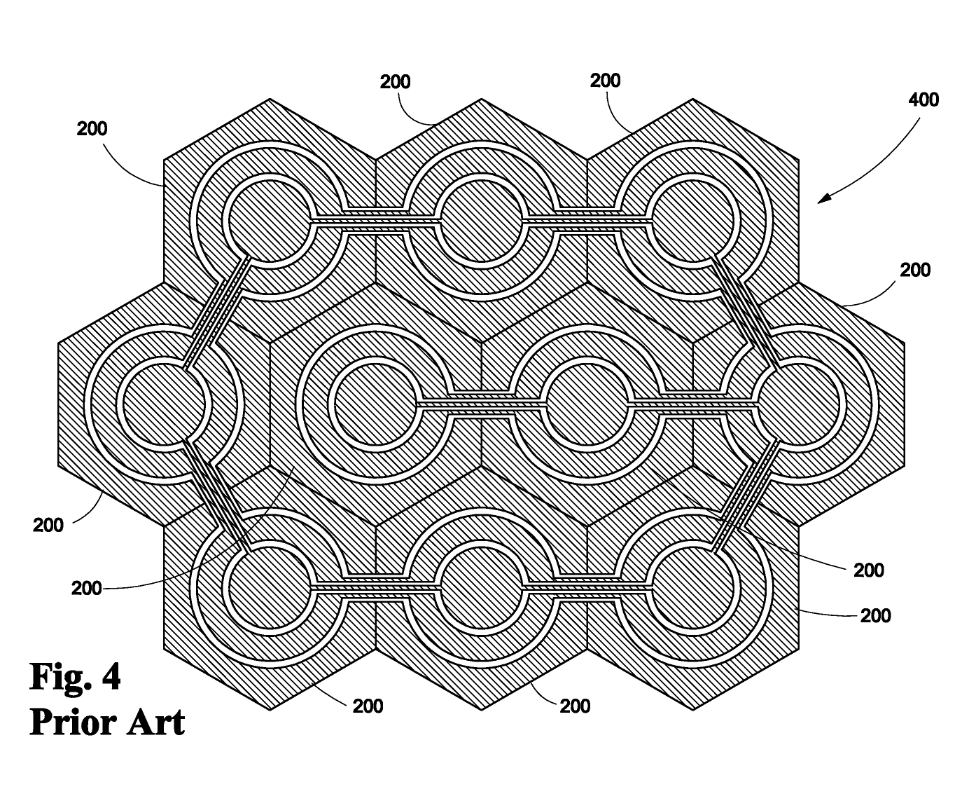

In this embodiment, the layout for the physically segmented and biased entrance windows is as shown in FIG. 3. Such a configuration allows easier and less obstructive bonding, as well as the possibility of arranging them into monolithic arrays 400 such as the one shown in FIG. 4, where the entrance windows of multiple detector elements can be biased as a group from a small single biasing area outside of the active area. However, according to the arrays 400 described herein, detector elements 200 are arranged in a non-planar fashion.

FIG. 3 is a plan view schematic of a semiconductor radiation detector element according to the embodiment shown in FIG. 2. The p+ doped regions 220, 222 are separated from one another by n+ regions 230. For ease of bonding and coupling to other entrance electrodes in an array configuration, each of the inner p+ regions 220, 222 and the n+ regions 230 are coupled to one or more leads. In this embodiment, p+ regions 220, 222 are coupled to p+ leads 300, and n+ regions 230 are coupled to n+ leads 310.

FIG. 4 is a plan view schematic of a prior art array 400 of detector elements 200 according to the embodiment shown in FIG. 2 arranged in a planar fashion on a silicon wafer 270. This is an example of a monolithic array on a single silicon wafer 270. Using leads coupled to p+ regions and n+ regions, the p+ regions and the n+ regions of one detector element are coupled to corresponding p+ and n+ regions, respectively, of other detector elements. Since all the p+ regions and the n+ regions are coupled to corresponding p+ regions and the n+ regions, respectively, of all other detector elements, the entrance windows of all the detector elements may be biased as a group from a small single biasing area outside of the active area and/or the entrance window area. In those embodiments, the bonding pads do not obstruct the incoming radiation.

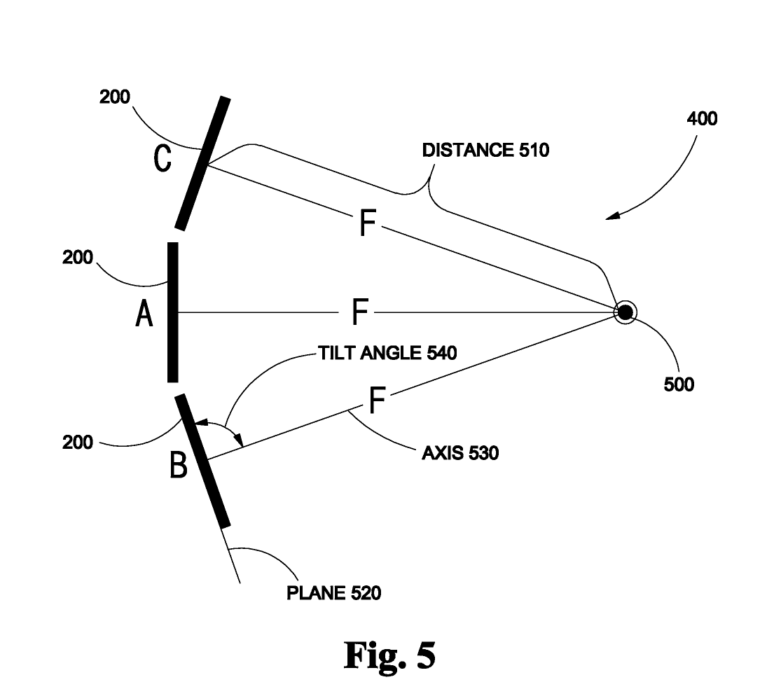

The systems described herein use an array 400 of detector elements 200 (such as those described in FIGS. 2-4) but arrange them in a non-planar array 400. This is illustrated graphically in FIG. 5. Each element 200 is arranged such that it has the same solid angle relative to a focal point 500, so that a sample located at the focal point 500 will deliver the same amount of radiation to each element 200. In some embodiments, each element 200 is the same size, and located at the same distance (or focal length 510) and the same tilt angle (90 degrees in the embodiment shown) relative to focal point 500. In other embodiments, the elements 200 are different sizes located at different distances 510 and/or tilt angles 540 relative to focal point 500, so long as the solid angle remains the same. In some embodiments, array 400 comprises three elements 200 that are 50 square millimeters each.

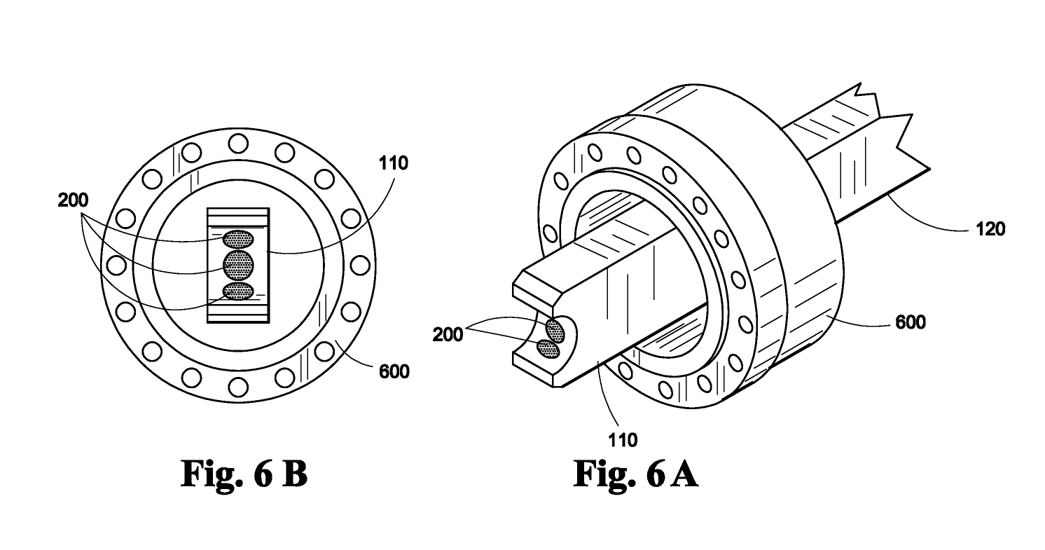

In FIG. 5, three equal-sized elements 200 are used and the same focal length and tilt angle 540. The central element, element A is located along the axis of probe 120 (as shown in FIGS. 1, 6A, and 6B) and is aligned with the subject being scanned at focal point 500. The other two elements B, C are arranged on either side of element A and are tilted toward focal point 500. Elements B and C are also configured to have the same focal length 510 and same tilt angle 540 (90 degrees) as element A. As a result of this configuration, the relative solid angles of elements A, B, and C get closer and closer as the subject is moved away from probe tip 110 and intersect at the focal point 500 at focal length 510 (30 mm in some embodiments).

In some embodiments, all of the elements 200 are facing focal point 500 such that their major planes 520 are normal to an axis 530 intersecting the center of element 200 and focal point 500 (i.e. a tilt angle 540 of 90 degrees). Elements 200 may be arranged in several geometric shapes relative to focal point 500, such as in a spherical arrangement or in a parabolic arrangement. Elements 200 may be electrically connected to each other, and/or abutted to each other such as is shown in the prior art array 400 of FIG. 4. As can be seen, the arrangement in FIG. 5 results in the central axes 530 (that intersect the centers of elements 200 and focal point 500) all being located in the same plane.

Detection elements 200 are connected to a control circuit that detects electrical impulses caused by radiation incident on detection elements 200. The performance of the control circuitry (and the detector 100 overall) is improved when the radiation on each element 200 can be assumed to be equal. Thus, a multi-element focal array 400 is advantageous because each element 200 is irradiated the same amount. This is not possible with a planar array 400 as shown in FIG. 4, because the elements 200 in that arrangement will not have equal solid angles (or tilt angles) with respect to a point on sample placed in front of it.

Focal point 500 can be placed at a known distance in front of the detector probe tip 110. Thus, a technician can place samples at the known focal point 500 of the detector array 400 for optimal performance. By having a focal point 500 instead of a planar array 400 of detectors 200, a smaller solid angle of the sample is required to get good performance—since access to a planar surface of the sample is not required to get equal exposure to all of the elements 200. Therefore, in some embodiments it is possible to obtain scans from a longer distance with the focal array 400, if focal point 500 is set at a distance from detector probe tip 110. In some embodiments, it is also not necessary to use a long probe scanner 100 (or use electron focusing lenses), since focal point 500 (and sample) can be placed at a distance from probe tip 110.

FIGS. 6A and 6B show tip 110 of probe 120 of one embodiment of a long-probe radiation detector system 100 incorporating an array 400 of radiation detectors 200 according to one embodiment. As can be seen, tip 110 of probe 120 is concave to accommodate multiple detector elements 200 all focused on a single focal point 500. In this embodiment, the array 400 of detector elements 200 is a planar curve (with all of the central axes 530 in the same plane, as shown in FIG. 5), resulting in a concave curved tip shape. However, in embodiments where the array is bowl-shaped or cone-shaped, tip 110 may also be bowl-shaped or cone-shaped. Alternatively, tip 110 may have planar shape with an end that is at focal point 500 or between focal point 500 and array 400. This configuration could include a planar window at the end of tip 110, and would allow for easy identification of focal point 500 for scanning. In this embodiment, the central element 200 is aligned with shaft 120, such that the major axis of shaft 120 intersects the center of central element 200 and focal point 500.

The embodiment in FIGS. 6A and 6B also incorporates a bellow 600 that permits tip 110 to be inserted into a vacuum chamber while maintaining a hermetic seal and not breaking the vacuum. This is accomplished when bellow 600 sealingly engages a housing of the vacuum chamber, and allows for scanning of samples within the vacuum chamber.

Although the invention has been described with reference to embodiments herein, those embodiments do not limit the invention. Modifications to those embodiments or other embodiments may fall within the scope of the invention.

What is claimed is:

1. A radiation detector with improved performance, comprising:
a probe;
a first detector element constructed from planar semiconductor material in said probe;
a second detector element constructed from planar semiconductor material in said probe;
a focal point located outside of said probe; and
a circuit in communication with said detector elements;
said first and second detector elements facing said focal point and having the same solid angle relative to said focal point;
said detector elements generating signals in response to incident radiation; and
said circuit receiving the signals generated by said detector elements.

2. The detector of claim 1, further comprising:
a third detector element constructed from planar semiconductor material in said probe;
wherein said third detector faces said focal point and has the same solid angle relative to said focal point as said first and second detector elements.

3. The detector of claim 2, further comprising:
a first axis intersecting a center of said first detector element and said focal point;
a second axis intersecting a center of said second detector element and said focal point;
a third axis intersecting a center of said third detector element and said focal point;
wherein said first, second, and third axes are located in one plane.

4. The detector of claim 1, further comprising:
a housing;
a proximal portion of said probe coupled to said housing; and
a distal portion of said probe that contains said detector elements.

5. The detector of claim 1, further comprising:
a probe axis that intersects said proximal portion and distal portion of said probe;
said probe axis also intersecting a center of said first detector element and said focal point.

6. The detector of claim 1, wherein said first and second detector elements abut one another.

7. The detector of claim 1, wherein said first and second detector elements are electrically connected to each other.

8. The detector of claim 1, further comprising:
a first axis intersecting a center of said first detector element and said focal point;
a first major plane of said first detector element, said first axis being normal to said first major plane;
a second axis intersecting a center of said second detector element and said focal point; and
a second major plane of said second detector element, said second axis being normal to said second major plane.

9. The detector of claim 1, wherein the planar semiconductor material is a silicon wafer.

10. The detector of claim 1, wherein the detector is an x-ray detector.

11. The detector of claim 1, wherein said probe has a concave tip.

12. The detector of claim 1, further comprising:
a bellow surrounding the probe that sealingly engages a housing of a vacuum chamber.

13. A semiconductor radiation detector array with improved performance, comprising:
a first detector element constructed from planar semiconductor material;
a second detector element constructed from planar semiconductor material; and
a focal point;
said first and second detector elements facing said focal point and having the same solid angle relative to said focal point.

14. The array of claim 13, further comprising:
a third detector element constructed from planar semiconductor material;
wherein said third detector faces said focal point and has the same solid angle relative to said focal point as said first and second detector elements.

15. The array of claim 14, further comprising:
a first axis intersecting a center of said first detector element and said focal point;
a second axis intersecting a center of said second detector element and said focal point;
a third axis intersecting a center of said third detector element and said focal point;
wherein said first, second, and third axes are located in one plane.

16. The array of claim 13, wherein said first and second detector elements abut one another.

17. The array of claim 13, wherein said first and second detector elements are electrically connected to each other.

18. The array of claim 13, further comprising:
a first axis intersecting a center of said first detector element and said focal point;
a first major plane of said first detector element, said first axis being normal to said first major plane;
a second axis intersecting a center of said second detector element and said focal point; and
a second major plane of said second detector element, said second axis being normal to said second major plane.

19. The array of claim 13, wherein the planar semiconductor material is a silicon wafer.

20. The array of claim 13, wherein the array is an x-ray detector.
